(19) United States
(12) Patent Application Publication
(10) Pub. No.: US 2015/0034365 A1
(43) Pub. Date: Feb. 5, 2015

(54) METHOD FOR MANUFACTURING WIRING BOARD AND WIRING BOARD

(71) Applicant: IBIDEN CO., LTD., Ogaki-shi (JP)

(72) Inventors: Hiroyuki NISHIOKA, Ogaki-shi (JP); Shinsuke Ishikawa, Ogaki-shi (JP)

(73) Assignee: IBIDEN CO., LTD., Ogaki-shi (JP)

(21) Appl. No.: 14/447,687

(22) Filed: Jul. 31, 2014

(30) Foreign Application Priority Data
Aug. 1, 2013 (JP) 2013-160267

(51) Int. Cl. H05K 1/11; H05K 3/46

(52) U.S. Cl. CPC H05K 1/115; H05K 3/46
USPC 174/251; 216/20

(57) ABSTRACT

A method for manufacturing a wiring board includes preparing a wiring board having an insulation layer, a conductive pattern and a solder-resist layer laminated such that the solder-resist layer is covering the conductive pattern and exposing a conductive pad portion of the conductive pattern, applying microwave plasma on the wiring board in a nonoxidative atmosphere such that the wiring board undergoes microwave plasma treatment in the nonoxidative atmosphere, and forming a surface-treatment layer on the conductive pad portion of the conductive pattern after the applying of microwave plasma on the wiring board.

### CROSS-REFERENCE TO RELATED APPLICATIONS

The present application is based upon and claims the benefit of priority to Japanese Patent Application No. 2013-160267, filed Aug. 1, 2013, the entire contents of which are incorporated herein by reference.

### BACKGROUND OF THE INVENTION

1. Field of the Invention

The present invention relates to a wiring board formed with laminated conductive patterns and insulation layers. More specifically, the present invention relates to a method for manufacturing a wiring board in which a conductive pad is formed on part of a conductive pattern while the portion other than the conductive pad is covered with a solder-resist layer, and to such a wiring board.

2. Description of Background Art

JP H8-46038A relates to a wiring portion of a semiconductor device. In JP H8-46038A, via hole is formed by opening part of insulation film which covers wiring. In JP H8-46038A, plasma treatment is further conducted after via hole is opened. The entire contents of this publication are incorporated herein by reference.

### SUMMARY OF THE INVENTION

According to one aspect of the present invention, a method for manufacturing a wiring board includes preparing a wiring board having an insulation layer, a conductive pattern and a solder-resist layer laminated such that the solder-resist layer is covering the conductive pattern and exposing a conductive pad portion of the conductive pattern, applying microwave plasma on the wiring board in a nonoxidative atmosphere such that the wiring board undergoes microwave plasma treatment in the nonoxidative atmosphere, and forming a surface-treatment layer on the conductive pad portion of the conductive pattern after the applying of microwave plasma on the wiring board.

According to another aspect of the present invention, a wiring board includes an insulation layer, a conductive pattern formed on the insulation layer, and a solder-resist layer formed on the insulation layer and the conductive pattern such that the solder-resist layer is covering the conductive pattern and exposing a conductive pad portion of the conductive pattern. The conductive pad portion of the conductive pattern has a surface-treatment layer formed on the conductive pad portion of the conductive pattern, and the conductive pad portion of the conductive pattern forms a flat surface with respect to the conductive pattern covered with the solder-resist layer without a hollowing portion under the solder-resist layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view showing a state where an opening portion is formed in a solder-resist layer;

FIG. 2 is a cross-sectional view showing a state where the oxide film is removed by wet etching;

FIG. 3 is a cross-sectional view showing the structure of a wiring board according to an embodiment;

FIG. 4 is an enlarged cross-sectional view of a portion in FIG. 3;

FIG. 5 is a cross-sectional view showing a state where an opening portion is formed in a solder-resist layer;

FIG. 6 is a view schematically showing an example of the structure of a plasma-treatment apparatus;

FIG. 7 is a cross-sectional view showing a state after plasma treatment; and

FIG. 8 is a cross-sectional view showing a state where a solder bump is formed.

### DETAILED DESCRIPTION OF THE EMBODIMENTS

The embodiments will now be described with reference to the accompanying drawings, wherein like reference numerals designate corresponding or identical elements throughout the various drawings.

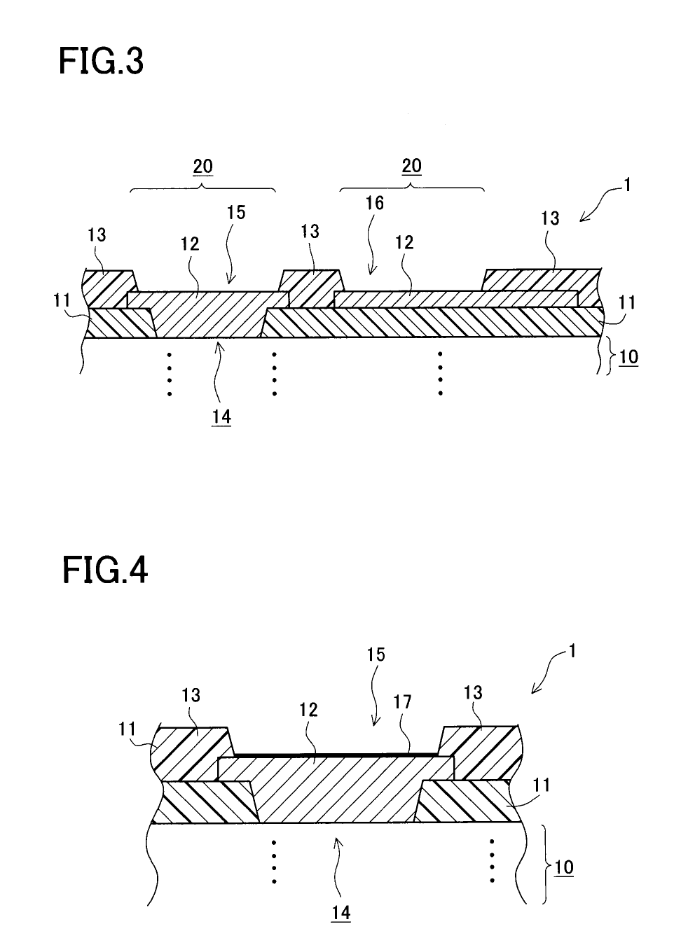

Wiring board 1 shown in FIG. 3 and the process for manufacturing wiring board 1 are embodiments of the present invention. Wiring board 1 is structured to have buildup insulation layer 11, upper conductive layer 12 and solder-resist layer 13, which are provided on lower section 10. Lower section 10 itself is a laminate of an insulation layer and a conductive layer. The structure of lower section 10 is not limited specifically, and any laminate may be used as long as it works as a wiring board formed by laminating an insulation layer and a conductive layer.

Via hole 14 is formed in a portion of buildup layer 11 shown in FIG. 3. Via hole 14 is a portion to connect upper conductive layer 12 and a conductive layer in lower section 10. At the portion where via hole 14 is formed, an opening is formed in buildup insulation layer 11 and the same metal as that of upper conductive layer 12 is filled in the opening.

Conductive pads (15, 16) for external connection are formed in upper conductive layer 12 shown in FIG. 3. Conductive pad 15 is formed in a portion directly on via hole 14, and the portion is part of the pattern of upper conductive layer 12. Conductive pad 16 is formed in a portion of the wiring that is not connected to via hole 14, and the portion is part of the pattern of upper conductive layer 12. Solder-resist layer 13 is a protective layer of wiring board 1 and covers the entire surface except for conductive pad portions of upper conductive layer 12 (conductive pads (15, 16) and other pads). Namely, openings 20 corresponding to positions of conductive pads (15, 16) are formed in solder-resist layer 13.

Here, surface-treatment layer 17 is formed on conductive pad 15, which is part of the surface of upper conductive layer 12 as shown in an enlarged view of FIG. 4. Surface-treatment layer 17 is any of a nickel-palladium-gold plated layer, a nickel-gold plated layer and a preflux film (OSP film). In addition, the surface of upper conductive layer 12 is made flat, where no height variations are observed between a portion directly under surface-treatment layer 17 and a portion directly under solder-resist layer 13. Moreover, surface-treatment layer 17 is present only within the range of an opening of solder-resist layer 13 where conductive pad 15 is positioned. In other words, the periphery of surface-treatment layer 17 does not extend under solder-resist layer 13 to cause hollowing. Also, the same structure applies to the portion of conductive pad 16 except that no via hole 14 is formed.

Next, the process is described for manufacturing wiring board 1 shown in FIG. 3. Wiring board 1 is manufactured following the steps below.
1. formation of solder-resist layer
2. plasma treatment
3. surface treatment of pad

### 1. Formation of Solder-Resist Layer

A starting material is selected, and lamination, patterning and formation of holes are repeated to form lower section 10. Then, buildup insulation layer 11 is formed and processed, upper conductive layer 12 is formed and patterned, and solder-resist layer 13 is formed, processed and thermally cured. To process buildup insulation layer 11 means to form an opening in a position for via hole 14. The upper circuit pattern formed by patterning upper conductive layer 12 includes portions that become conductive pads (15, 16). To process solder-resist layer 13 means to form openings in positions for conductive pads (15, 16) by photolithography or the like, for example.

Here, solder-resist layer 13 is formed using a liquid- or film-type photosensitive resin that contains inorganic filler. The diameter of the inorganic filler is in a range of 0.1˜10 μm, and its component is silica or barium sulfate. The amount of inorganic filler in the photosensitive resin is in a range of 15˜70 wt. %. Examples of photosensitive resin are epoxy acrylate resins, phenolic epoxy resins and phenolic cyanate resins, and commercially available products are, for example, SR7200 series (liquid type) and SR7300 series (liquid type) made by Hitachi Chemical Co., Ltd., SR-1 series (film type) made by Taiyo Ink Mfg. Co., Ltd. and the like.

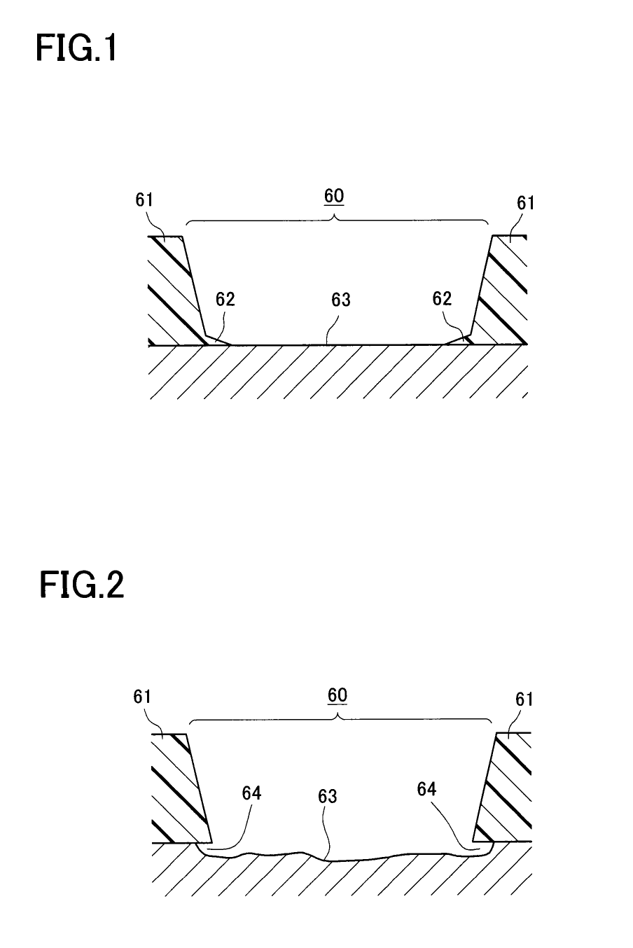

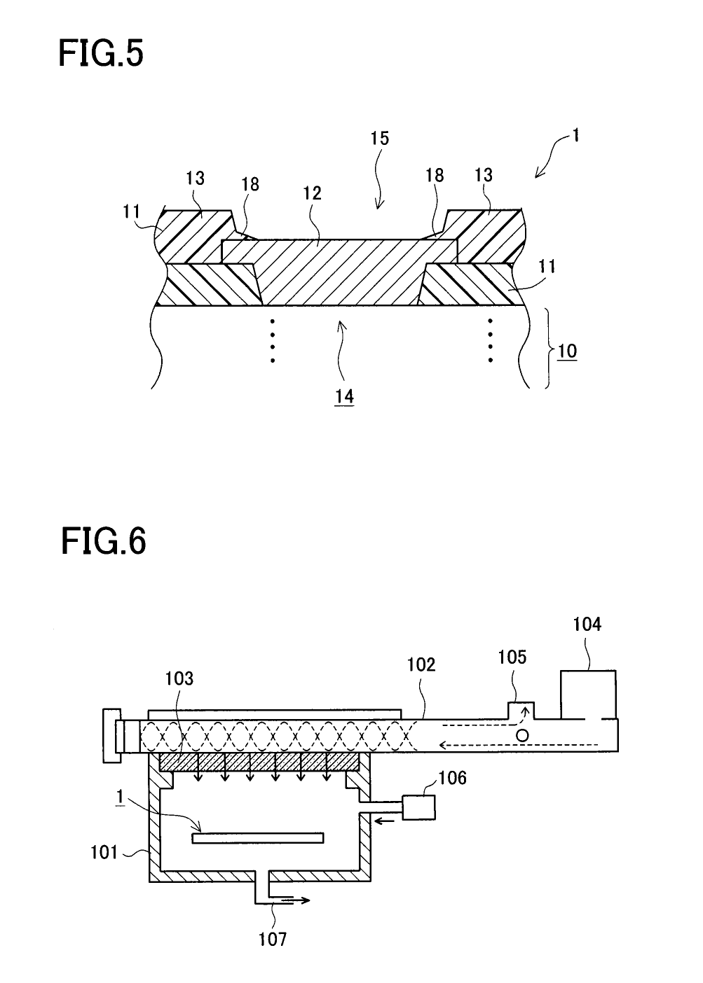

FIG. 5 shows the position of conductive pad 15 shown in FIG. 3 at this stage, that is, the same portion shown in FIG. 4. Namely, most portions shown in FIG. 3 have been already formed here. However, surface-treatment layer 17 is not formed yet at this stage. In addition, at the bottom tip of the opening portion in solder-resist layer 13, residual edge 18 is present. That corresponds to residual edge 62 described in FIG. 1. A residual edge is also present at the bottom tip of an opening portion in solder-resist layer 13 corresponding to conductive pad 16 in FIG. 3.

### 2. Plasma Treatment

Plasma treatment is conducted on wiring board 1 in a state shown in FIG. 5. For plasma treatment here, an apparatus shown in FIG. 6 is used, for example. The plasma treatment apparatus in FIG. 6 has process vessel 101, waveguide 102, dielectric divider wall 103, oscillator 104, isolator 105 and gas-supply device 106. Exhaust outlet 107 is provided in process vessel 101. Exhaust outlet 107 is connected to an external vacuum pump (not shown).

When a microwave is generated by oscillator 104, the microwave propagates through waveguide 102 and generates plasma in process vessel 101 by way of dielectric divider wall 103. At that time, process vessel 101 is maintained under a certain gas composition and a certain pressure due to the gas supply from gas-supply device 106 and suction through exhaust outlet 107. In addition, the reflected wave component of the microwave in waveguide 102 is removed by isolator 105. Accordingly, plasma treatment is performed on wiring board 1 placed inside process vessel 101.

In the plasma treatment of the present embodiment, a nonoxidative gas is used as the gas to be introduced into process vessel 101. In particular, a mixed gas of N₂ gas and H₂ gas is used, namely, a mixed gas of inert gas and reducing gas. Instead of N₂ gas, a rare gas such as Ar gas or Ne gas or a combination thereof may be used as an inert gas.

Examples of further detailed conditions for the gas and microwaves are shown below.
pressure: 25˜100 Pa
H₂ gas concentration: 0.1˜5% (volume ratio)
flow rate: 300˜1200 sccm (N₂), 10˜50 sccm (H₂)
frequency of microwave: 2.56 GHz
power supply: 3 kW
processing time: 20˜60 sec.
processing temperature: 150° C. or lower

Due to plasma treatment in a nonoxidative atmosphere, the following two changes occur in wiring board 1. One is residue removal from solder-resist layer 13, and the other is reduction on the surface of upper conductive layer 12.

The residue of solder-resist layer 13 means fine particles of the components of solder-resist layer 13 (mainly inorganic filler) generated during the process for forming an opening in solder-resist layer 13 (laser processing or the like). Such residue is attached to the bottom surface (that is, the surface of conductive pad 15 or 16) and side-wall surface of an opening in solder-resist layer 13, and remains after solder-resist layer 13 has been thermally cured. Plasma treatment removes such residue. The removal of residue is conducted not through chemical processing of the gas in process vessel 101 but through physical removal by high-energy molecules or ions in the gas. Such a removal process also removes residual edge 18 from the bottom tip of an opening portion of solder-resist layer 13 shown in FIG. 5.

The other change that occurs in wiring board 1 during plasma treatment is reduction on the surface of upper conductive layer 12. The material of upper conductive layer 12 is usually copper, and an oxidized layer produced through contact with atmospheric air is inevitably formed on its surface. The gas for plasma treatment contains H₂ gas, thus reduction of the oxidized layer occurs on the surface of upper conductive layer 12.

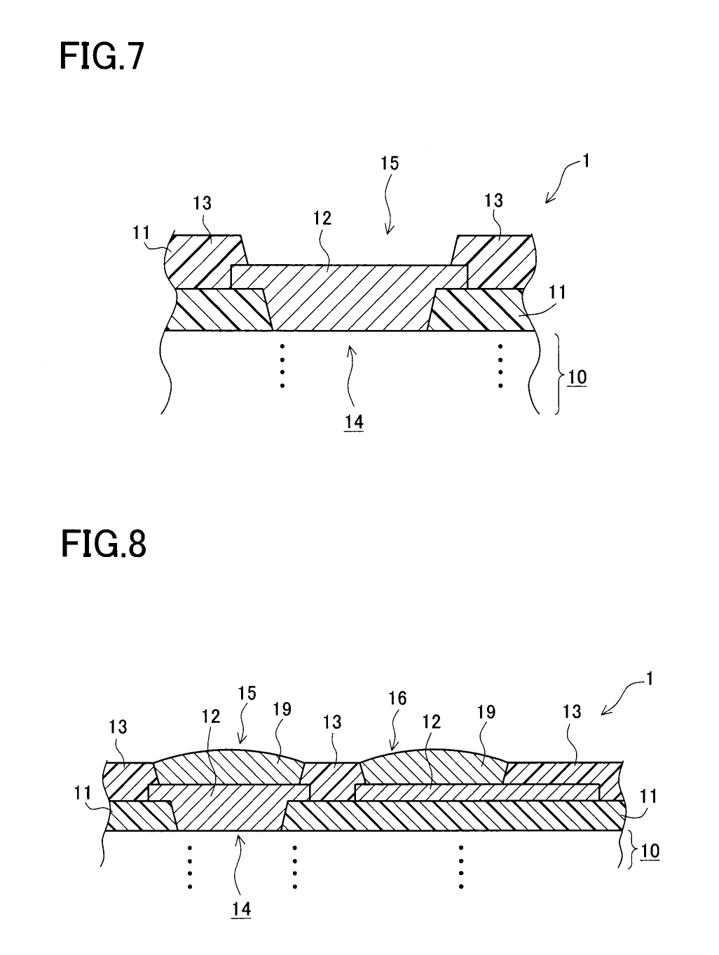

The portion of wiring board 1 shown in FIG. 5 becomes a state shown in FIG. 7 after plasma treatment. Unlike wiring board 1 in FIG. 5, residual edge 18 at the bottom tip of an opening portion of solder-resist layer 13 has been removed in FIG. 7. In addition, although it is not clear in FIG. 7, the surface of upper conductive layer 12 is a clean surface where the oxidized layer is almost completely gone. Meanwhile, on the surface of upper conductive layer 12, there are no height variations between a portion covered with solder-resist layer 13 and an uncovered portion. Namely, the state shown in FIG. 2 is not observed. That is because plasma treatment does not etch the surface of upper conductive layer 12 but only causes reduction of the oxidized layer. That means wedge-shaped space 64 shown in FIG. 2 does not exist in wiring board 1 shown in FIG. 7. The same applies to the position corresponding to conductive pad 16 shown in FIG. 3.

### 3. Surface Treatment of Pad

Surface treatment of a pad is conducted on wiring board 1 after the plasma treatment. Namely, surface-treatment layer 17 shown in FIG. 4 is formed. Any known method is employed for forming surface-treatment layer 17 itself. Accordingly, the state shown in FIG. 4 is obtained. At this time, adhesiveness is strong between the surface of upper conductive layer 12 and surface-treatment layer 17 formed thereon, because reduction on the surface of upper conductive layer 12 has been carried out by plasma treatment and surface treatment has been conducted on the layer from which the oxidized layer is almost completely gone. Unlike the surface shown in FIG. 2, surface-treatment layer 17 is formed only within the range of an opening in solder-resist layer 13. Namely, no hollowing observed, because wedge-shaped space 64 shown in FIG. 2 is not formed on the surface shown in FIG. 7. Therefore, short-circuiting of adjacent conductive pads is unlikely to occur. The same also applies to conductive pad 16 shown in FIG. 3.

Wiring board 1 shown in FIG. 3 is completed by the process described above. For the wiring board shown in FIG. 3, solder bumps are subsequently formed on conductive pads (15, 16). Either a method for loading solder balls or a printing method may be employed to form solder bumps. A state where solder bumps are formed is shown in FIG. 8. Solder bumps after a reflow process are shown in FIG. 8. In wiring board 1 of FIG. 8, upper conductive layer 12, along with conductive pads (15, 16), is covered with solder bump 19. Opening portions of solder-resist layer 13 are filled with solder bumps 19. Adhesiveness is strong between upper conductive layer 12 and solder bump 19 in a state shown in FIG. 8, because excellent formation of surface-treatment layer 17 is achieved after the surface of upper conductive layer 12 is cleaned through plasma treatment. In addition, top heights of solder bumps 19 are arrayed accurately in a state shown in FIG. 8, because upper conductive layer 12 is not affected by wet etching and has excellent flatness.

When surface-treatment layer 17 shown in FIG. 4 is made of a nickel-palladium-gold plated layer or a nickel-gold plated layer, surface-treatment layer 17 is actually present between upper conductive layer 12 and solder bump 19 in a state shown in FIG. 8. However, if surface-treatment layer 17 is made of preflux film, the presence of preflux film is not clear in a state shown in FIG. 8, although effects of plasma treatment are still observed. Here, without forming surface-treatment layer 17, solder bump 19 may be formed directly on upper conductive layer 12 after plasma treatment has been conducted. Namely, it is an option to set solder bump 19 as a surface-treatment layer. In such a case as well, due to plasma treatment, strong adhesiveness is obtained between upper conductive layer 12 and solder bump 19, compared with a case where no plasma treatment is conducted.

As described in detail above, according to the present embodiment, plasma treatment is conducted after processing and curing solder-resist layer 13 when wiring board 1 shown in FIG. 3 is manufactured. Accordingly, processing residue of solder-resist layer 13 and its residual edge 18 are removed without conducting wet etching. Moreover, since a reducing atmosphere is used for the inner ambient of plasma treatment, reduction of the oxidized layer on the surface of upper conductive layer 12 is achieved without conducting wet etching.

Therefore, after performing plasma treatment in portions of conductive pads (15, 16) on the surface of upper conductive layer 12, normal properties without an oxidized layer and flatness without height variations between a portion covered with solder-resist layer 13 and an uncovered portion are both achieved. Accordingly, there is no space resulting from etching that extends between the lower surface of solder-resist layer 13 and upper conductive layer 12. Thus, no hollowing occurs on surface-treatment layer 17 in the subsequent surface-treatment step. Accordingly, wiring board 1 is obtained where short-circuiting of adjacent pads is unlikely to occur. Also, height accuracy is improved when solder bumps 19 are formed in portions of conductive pads (15, 16).

The embodiments above are simply examples of the present invention and do not limit the present invention in any way. Obviously, various improvements and modifications are possible within a scope that does not deviate from the gist of the present invention. For example, the material for upper conductive layer 12 is not limited to copper, and any conductive material such as nickel or aluminum may also be used. In addition, the material for interlayer insulation layers is not limited specifically as long as it satisfies conditions such as insulation and strength.

When a wiring board is formed, the insulation layer formed on a conductive pattern that includes a conductive pad may be a solder-resist layer. When an opening is made in a solder-resist layer, residual edge 62 of solder-resist layer 61 tends to remain on the periphery of the bottom of opening 60, as shown in FIG. 1. Thus, plasma treatment is conducted to remove residual edge 62 of the solder-resist layer. Such plasma treatment is conducted in an oxygen-gas atmosphere. However, the natural oxidation on the surface of conductive pad 63 cannot be removed by plasma treatment in an oxygen-gas atmosphere. On the contrary, the thickness of the oxide film increases.

Therefore, another treatment for removal of oxide film is further conducted after plasma treatment. Namely, many steps are taken before surface treatment is ready to be conducted on the conductive pad. In addition, wet etching may be used for removing oxide film. In such a case, etching may extend beneath the solder-resist layer. Thus, as shown in FIG. 2, wedge-shaped space 64, formed on the periphery of opening portion 60, results from etching that extends between the lower surface of solder-resist layer 61 and conductive-pad surface 63. Under such circumstances, metal ion concentrations in the etching solution may vary depending on positions. Thus, the flatness of conductive-pad surface 63 is lowered.

Moreover, when surface treatment is conducted where wedge-shaped space 64 is present, the surface-treatment solution enters space 64. Thus, a surface-treatment layer is formed a little wider than opening portion 60, spreading under solder-resist layer 61. That is called as hollowing. Hollowing is not preferred, since it may cause short-circuiting of adjacent conductive pads.

A method for manufacturing a wiring board according to an embodiment of the present invention can prevent formation of spaces under a solder-resist layer, achieves excellent flatness on surfaces of conductive pads, separates conductive pads well from each other, and provides such a wiring board.

A method for manufacturing a wiring board according to an embodiment of the present invention includes the following: a preparation step for preparing a wiring board where a conductive pattern and an insulation layer are laminated, the conductive pattern includes a conductive pad, and the conductive pattern except for the conductive pad is covered with a solder-resist layer; a plasma-treatment step for conducting microwave plasma treatment on the wiring board prepared in the preparation step; and a surface-treatment-layer forming step for forming a surface-treatment layer on the conductive pad after the plasma-treatment step has been conducted on the wiring board.

In the method for manufacturing a wiring board according to the above embodiment, a portion of a conductive pattern that becomes a conductive pad is exposed by processing the solder-resist layer, and a plasma-treatment step is conducted prior to conducting a surface-treatment-layer forming step. Thus, the solder-resist layer after such processing and the exposed conductive pad are cleaned. Especially, residual solder resist remaining on the bottom of an opening portion of the solder-resist layer and the protruding portion at a bottom tip are removed during the plasma-treatment step. Since the surface-treatment-layer forming step is conducted after such cleaning, the adhesiveness of the surface-treatment layer to a conductive pad is strong.

In addition, a conductive pad is not etched in a plasma-treatment step. Thus, in the upper conductive layer, height variations do not exist between a portion covered by the solder-resist layer and the exposed conductive-pad portion. Also, on the periphery of an opening portion of the solder-resist layer, no wedge-shaped space is formed between the lower portion of the solder-resist layer and the upper conductive layer. Thus, a surface-treatment layer is formed without so-called hollowing. In addition, excellent flatness is achieved for the conductive pad. The solder-resist layer of a wiring board obtained in the preparation step is preferred to be formed using a liquid- or film-type photosensitive resin containing inorganic filler with a diameter of 0.1˜10 μm at 15˜70 wt. %.

Moreover, in the method for manufacturing a wiring board according to the above embodiment, the plasma-treatment step is preferred to be conducted in a mixed atmosphere of inert gas and hydrogen gas. Under such conditions, even if an oxidized layer is formed on the upper conductive layer surface, reduction of the oxidized layer occurs on the portion of a conductive pad exposed from the solder-resist layer during the plasma-treatment step. Thus, stronger adhesiveness is achieved between the upper conductive layer and the surface-treatment layer.

In addition, in the manufacturing method of a wiring board according to the above embodiment, the surface-treatment layer formed in the surface-treatment-layer forming step is preferred to be a layer selected from among a nickel-palladium-gold plated layer, a nickel-gold plated layer and a preflux film. By so setting, even stronger adhesiveness is achieved between a conductive pad and the surface-treatment layer. Also, a layer to be formed on a conductive pad may be a solder-bump layer. Generally, a solder-bump layer is formed on the above plated layer or the like, but it is also an option to form a solder-bump layer directly on a conductive pad.

Furthermore, in a wiring board according to another embodiment of the present invention, a conductive pattern and an insulation layer are laminated, and a conductive pad is formed on a portion of the conductive pattern. In such a wiring board, a solder-resist layer covers the conductive pattern while having an opening on the portion of a conductive pad, and a surface-treatment layer is formed on the conductive pad. On the periphery of the conductive pad, etching does not extend under the solder-resist layer to create space, and the conductive pad portion and the lower part of the solder-resist layer form a flat surface.

A manufacturing method according to an embodiment of the present invention provides a wiring board where etching does not extend under the solder-resist layer, excellent flatness is achieved on surfaces of conductive pads, and conductive pads are well separated from each other. An embodiment of the present invention also provides such a wiring board.

Obviously, numerous modifications and variations of the present invention are possible in light of the above teachings. It is therefore to be understood that within the scope of the appended claims, the invention may be practiced otherwise than as specifically described herein.

What is claimed is:

1. A method for manufacturing a wiring board, comprising:
preparing a wiring board comprising an insulation layer, a conductive pattern and a solder-resist layer laminated such that the solder-resist layer is covering the conductive pattern and exposing a conductive pad portion of the conductive pattern;
applying microwave plasma on the wiring board in a nonoxidative atmosphere such that the wiring board undergoes microwave plasma treatment in the nonoxidative atmosphere; and
forming a surface-treatment layer on the conductive pad portion of the conductive pattern after the applying of microwave plasma on the wiring board.

2. A method for manufacturing a wiring board according to claim 1, wherein the nonoxidative atmosphere is a mixed atmosphere including an inert gas and a hydrogen gas.

3. A method for manufacturing a wiring board according to claim 1, wherein the microwave plasma is applied such that an oxidized layer formed on a surface of the conductive pad portion of the conductive pattern undergoes reduction.

4. A method for manufacturing a wiring board according to claim 2, wherein the microwave plasma is applied such that an oxidized layer formed on a surface of the conductive pad portion of the conductive pattern undergoes reduction.

5. A method for manufacturing a wiring board according to claim 1, wherein the microwave plasma is applied such that residual solder resist is removed from an opening portion of the solder-resist layer exposing the conductive pad portion of the conductive pattern.

6. A method for manufacturing a wiring board according to claim 2, wherein the microwave plasma is applied such that residual solder resist is removed from an opening portion of the solder-resist layer exposing the conductive pad portion of the conductive pattern.

7. A method for manufacturing a wiring board according to claim 3, wherein the microwave plasma is applied such that residual solder resist is removed from an opening portion of the solder-resist layer exposing the conductive pad portion of the conductive pattern.

8. A method for manufacturing a wiring board according to claim 1, wherein the solder-resist layer of the wiring board comprises a photosensitive resin including inorganic filler having a diameter in a range of 0.1˜10 μm in an amount in a range of 15˜70 wt. %.

9. A method for manufacturing a wiring board according to claim 2, wherein the solder-resist layer of the wiring board comprises a photosensitive resin including inorganic filler having a diameter in a range of 0.1˜10 μm in an amount in a range of 15˜70 wt. %.

10. A method for manufacturing a wiring board according to claim 3, wherein the solder-resist layer of the wiring board comprises a photosensitive resin including inorganic filler having a diameter in a range of 0.1˜10 μm in an amount in a range of 15˜70 wt. %.

11. A method for manufacturing a wiring board according to claim 1, wherein the forming of the surface-treatment layer comprises forming a layer selected from the group consisting of a nickel-palladium-gold plated layer, a nickel-gold plated layer and a preflux film.

12. A method for manufacturing a wiring board according to claim 2, wherein the forming of the surface-treatment layer comprises forming a layer selected from the group consisting of a nickel-palladium-gold plated layer, a nickel-gold plated layer and a preflux film.

13. A method for manufacturing a wiring board according to claim 3, wherein the forming of the surface-treatment layer comprises forming a layer selected from the group consisting of a nickel-palladium-gold plated layer, a nickel-gold plated layer and a preflux film.

14. A method for manufacturing a wiring board according to claim 1, wherein the forming of the surface-treatment layer comprises forming a solder-bump layer on the conductive pad portion of the conductive pattern.

15. A method for manufacturing a wiring board according to claim 2, wherein the forming of the surface-treatment layer comprises forming a solder-bump layer on the conductive pad portion of the conductive pattern.

16. A method for manufacturing a wiring board according to claim 3, wherein the forming of the surface-treatment layer comprises forming a solder-bump layer on the conductive pad portion of the conductive pattern.

17. A wiring board, comprising:
an insulation layer;
a conductive pattern formed on the insulation layer; and
a solder-resist layer formed on the insulation layer and the conductive pattern such that the solder-resist layer is covering the conductive pattern and exposing a conductive pad portion of the conductive pattern,
wherein the conductive pad portion of the conductive pattern has a surface-treatment layer formed on the conductive pad portion of the conductive pattern, and the conductive pad portion of the conductive pattern forms a flat surface with respect to the conductive pattern covered with the solder-resist layer without a hollowing portion under the solder-resist layer.

18. A wiring board according to claim 17, wherein the solder-resist layer comprises a photosensitive resin including inorganic filler having a diameter in a range of 0.1˜10 μm in an amount in a range of 15˜70 wt. %.

19. A wiring board according to claim 17, wherein the surface-treatment layer comprises a layer selected from the group consisting of a nickel-palladium-gold plated layer, a nickel-gold plated layer, and a preflux film.

20. A wiring board according to claim 17, wherein the surface-treatment layer comprises a solder-bump layer formed on the conductive pad portion of the conductive pattern.
